(19) United States
(12) Patent Application Publication
(10) Pub. No.: US 2013/0299863 A1
(43) Pub. Date: Nov. 14, 2013

(54) LIGHT-EMITTING DIODE STRUCTURE AND METHOD FOR MANUFACTURING THE SAME

(71) Applicant: CHI MEI LIGHTING TECHNOLOGY CORP., Tainan (TW)

(72) Inventors: Chang Hsin Chu, Tainan (TW); Kuo Hui Yu, Tainan (TW); Wen Hung Chuang, Tainan (TW)

(73) Assignee: Chi Mei Lighting Technology Corp., Tainan (TW)

(21) Appl. No.: 13/887,703

(22) Filed: May 6, 2013

(30) Foreign Application Priority Data
May 8, 2012 (TW) 101116363

(51) Int. Cl. H01L 33/58

(52) U.S. Cl. CPC H01L 33/58
USPC 257/98; 438/29

(57) ABSTRACT

An LED structure include a substrate, a light-emitting structure disposed on the substrate, at least one surface plasmon (SP) structure, and a first and a second electrodes. The light-emitting structure has a first electrical type semiconductor layer, an active layer, a second electrical type semiconductor layer, and a first conductive layer sequentially stacked. The active layer is located at a first portion of the first electrical type semiconductor layer and exposed from a second portion of the first electrical type semiconductor layer. The first and the second electrical type semiconductor layer have different electrical types. The SP structure is concavely disposed in the first conductive layer and the second electrical type semiconductor layer. The first and the second electrodes are disposed on the second portion of the first electrical type semiconductor layer and the first conductive layer, respectively. A method for manufacturing the above LED structure.

### CROSS-REFERENCE TO RELATED APPLICATIONS

This non-provisional application claims priority under 35 U.S.C. §119(a) on Patent Application No. 101116363 filed in Taiwan, R.O.C. on May 8, 2012, the entire contents of which are hereby incorporated by reference.

Some references, if any, which may include patents, patent applications and various publications, may be cited and discussed in the description of this invention. The citation and/or discussion of such references, if any, is provided merely to clarify the description of the present invention and is not an admission that any such reference is “prior art” to the invention described herein. All references listed, cited and/or discussed in this specification are incorporated herein by reference in their entireties and to the same extent as if each reference was individually incorporated by reference.

### FIELD OF THE INVENTION

The present invention relates generally to a light-emitting element, and more particularly to a light-emitting diode (LED) structure and a method for manufacturing the same.

### BACKGROUND OF THE INVENTION

FIG. 1 is a sectional view of an LED structure in a conventional surface plasmon (SP) mode. An LED structure 100 in such an SP mode includes a substrate 102, an epitaxial structure 110, a resonant metal layer 112, an n-type electrode 114, and a p-type electrode 116. The epitaxial structure 110 includes an n-type semiconductor layer 104, an active layer 106, and a p-type semiconductor layer 108 sequentially stacked on the substrate 102. The resonant metal layer 112 is disposed on the p-type semiconductor layer 108, and the p-type electrode 116 is disposed on the resonant metal layer 112. The n-type electrode 114 is disposed at an exposed portion of the n-type semiconductor layer 104.

In the LED structure 100 in such an SP mode, the energy of photons emitted from the active layer 106 can be transferred to the resonant metal layer 112 disposed on the p-type semiconductor layer 108. The resonant metal layer 112, upon absorbing the energy transferred from the photons, presents the energy in a photon mode or an SP mode, and generates an electromagnetic field. The electromagnetic field generated by the resonant metal layer 112 excites the active layer 106 in turn. Therefore, the active layer 106 emits more photons, thereby further enhancing the light emitting efficiency of the LED structure 100. In addition, the resonant metal layer 112 can emit the absorbed photons again, so as to solve the problem of total internal reflection that occurs due to an excessively large refractive index difference between the semiconductor material layer and the air interface, thereby further enhancing the light extraction efficiency of the LED structure 100.

However, the thickness of the p-type semiconductor layer 108 is often about thousands of angstroms (Å). Therefore, a distance is present between the resonant metal layer 112 located on the p-type semiconductor layer 108 and the active layer 106. Therefore, the photon coupling efficiency of the resonant metal layer 112 and the active layer 106 becomes undesirable, further causing that the effect of enhancing the light efficiency fails to meet the expectations.

To enhance the photon coupling efficiency of a resonant metal layer and an active layer, it is proposed in the industry to dispose a resonant metal layer between the n-type semiconductor layer and the active layer or to dispose a resonant metal layer between the active layer and the p-type semiconductor layer. Although such a structural design can make the resonant metal layer closer to the active layer, the epitaxial process of the epitaxial structure needs to be interrupted to deposit the resonant metal layer. Therefore, the epitaxial quality of the epitaxial structure is severely affected, and the light emitting efficiency of the epitaxial structure is significantly reduced.

### SUMMARY OF THE INVENTION

In one aspect, the present invention provides an LED structure and a method for manufacturing the same, in which an SP structure is concavely disposed in a light-emitting structure, so that the distance between a resonant metal layer of the SP structure and an active layer can be effectively reduced, so as to enhance the coupling efficiency of the resonant metal layer and the active layer, thereby further enhancing the internal quantum efficiency of the LED structure.

In another aspect, the present invention provides an LED structure and a method for manufacturing the same, which is capable of reducing the phenomenon of total internal reflection inside an LED structure by adjusting the material of an insulating layer in an SP structure, thereby further enhancing the external quantum efficiency of the LED structure.

An LED structure according to one embodiment of the present application includes a substrate, a light-emitting structure, at least one SP structure, and a first electrode and a second electrode. The light-emitting structure is disposed on the substrate, and includes a first electrical type semiconductor layer, an active layer, a second electrical type semiconductor layer, and a first conductive layer stacked sequentially on the substrate. The active layer is located on a first portion of the first electrical type semiconductor layer and is exposed from a second portion of the first electrical type semiconductor layer. The first electrical type semiconductor layer and the second electrical type semiconductor layer have different electrical types. The at least one SP structure is concavely disposed in the first conductive layer and the second electrical type semiconductor layer. The first electrode and the second electrode are disposed on the second portion of the first electrical type semiconductor layer and the first conductive layer, respectively.

In one embodiment, the at least one SP structure includes a plurality of SP bars or a plurality of SP dots.

In one embodiment, the light-emitting structure further includes at least one groove disposed in the first conductive layer and the second electrical type semiconductor layer, and the at least one SP structure is located in the at least one groove. The at least one SP structure includes a first insulating layer, a resonant metal layer, and a second insulating layer sequentially stacked.

In one embodiment, the distance between the bottom surface of the at least one groove and the active layer is from 50 Å to 1000 Å.

In one embodiment, the width of the bottom surface of the at least one SP structure is from 10 nm to 5 μm. In a preferred embodiment, the width of the bottom surface of the at least one SP structure is from 0.5 μm to 2 μm.

In one embodiment, the thickness of the resonant metal layer is from 5 Å to 500 Å.

In one embodiment, the material of the first insulating layer and the second insulating layer includes titanium dioxide (TiO₂), aluminum oxide (Al₂O₃), silicon dioxide (SiO₂) or silicon nitride (Si₃N₄).

In one embodiment, the refractive index of the first insulating layer is greater than the refractive index of the second insulating layer.

In one embodiment, the LED structure further includes a second conductive layer covering the first conductive layer and the at least one SP structure.

In one embodiment, the at least one SP structure includes a resonant metal layer.

In one embodiment, the at least one SP structure includes an insulating layer and a resonant metal layer covering the insulating layer.

A method for manufacturing an LED structure according to one embodiment of the present invention includes the following steps. A light-emitting structure is formed on a substrate. The light-emitting structure includes a first electrical type semiconductor layer, an active layer, a second electrical type semiconductor layer, and a first conductive layer sequentially stacked on the substrate. The active layer is located on a first portion of the first electrical type semiconductor layer and is exposed from a second portion of the first electrical type semiconductor layer. The first electrical type semiconductor layer and the second electrical type semiconductor layer have different electrical types. At least one groove is formed in the first conductive layer and the second electrical type semiconductor layer. At least one SP structure is formed in the at least one groove. A first electrode and a second electrode are formed on the second portion of the first electrical type semiconductor layer and the first conductive layer, respectively.

In one embodiment, the step of forming the at least one SP structure includes sequentially forming a first insulating layer, a resonant metal layer, and a second insulating layer to be filled in the at least one groove.

In one embodiment, between the step of forming the at least one SP structure and the step of forming the first electrode and the second electrode, the method for manufacturing an LED structure further includes forming a second conductive layer covering the first conductive layer and the at least one SP structure.

In one embodiment, the step of forming the at least one SP structure includes forming a resonant metal layer covering the at least one groove.

In one embodiment, the step of forming the at least one SP structure includes forming an insulating layer covering the at least one groove, and forming a resonant metal layer covering the insulating layer.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1 is a sectional view of an LED structure of a conventional SP mode;

FIG. 2A is a top view of an LED structure according to an embodiment of the present invention;

FIG. 2B is a sectional view of the LED structure obtained along the sectional line AA′ in FIG. 2A;

FIG. 2C is an enlarged view of an SP structure of an LED structure according to an embodiment of the present invention;

FIG. 3A to FIG. 3E are sectional views of a manufacturing process of an LED structure according to an embodiment of the present invention;

FIG. 4A is a top view of an LED structure according to another embodiment of the present invention; and

FIG. 4B is a sectional view of the LED structure obtained along the sectional line BB′ in FIG. 4A.

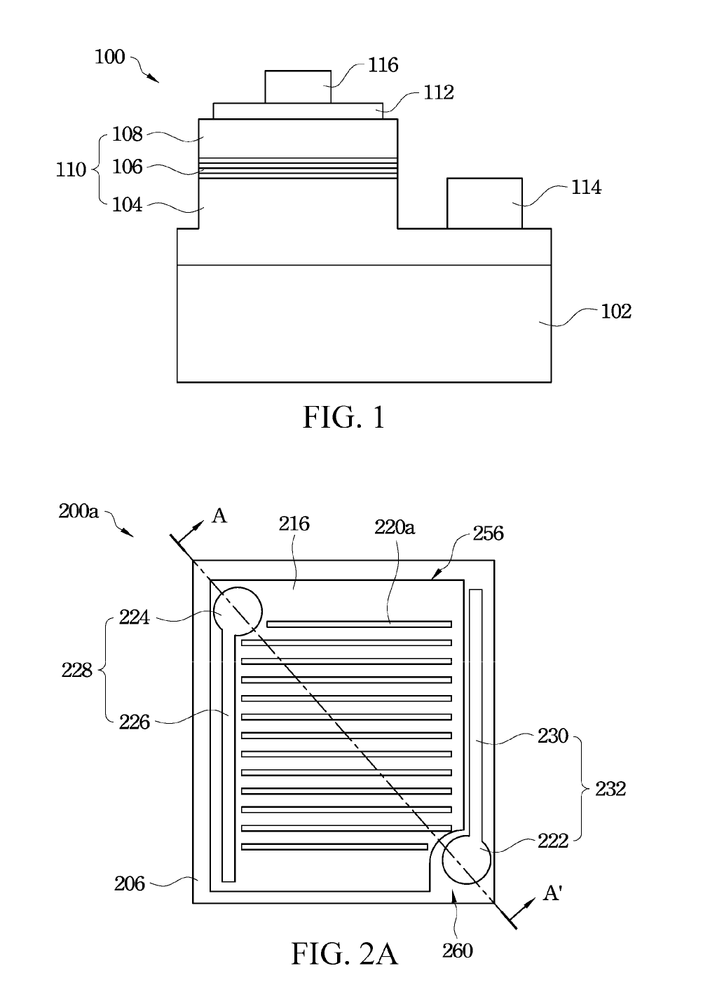

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing.

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

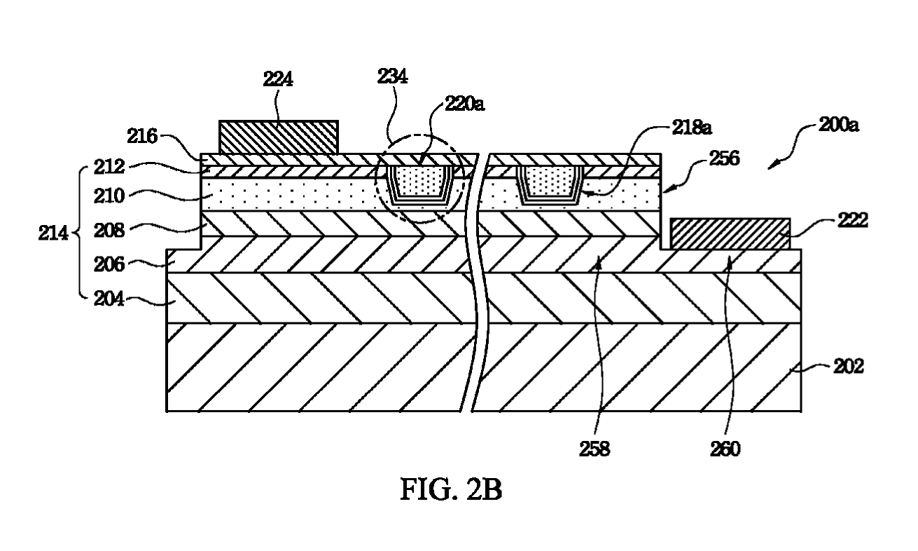

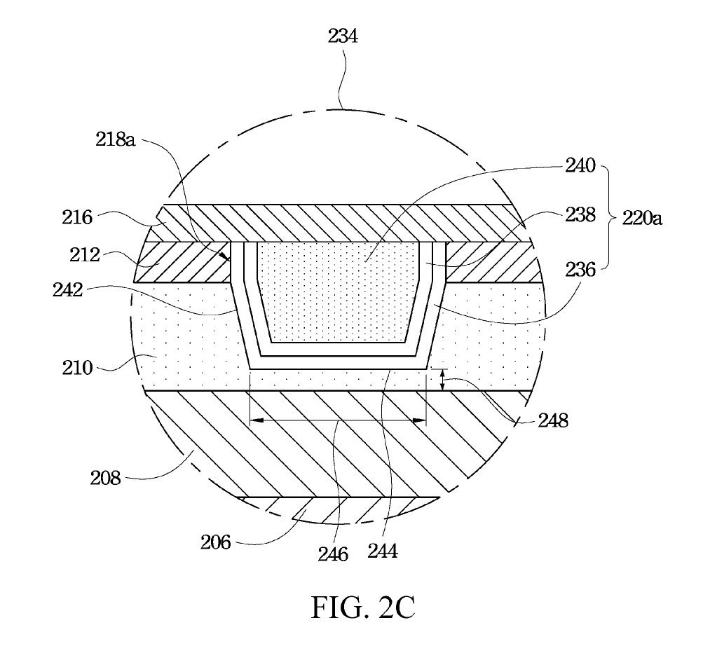

FIG. 2A is a top view of an LED structure according to one embodiment of the present invention, and FIG. 2B is a sectional view of the LED structure along the sectional line AA′ in FIG. 2A. In this embodiment, the LED structure 200a is a horizontal conduction LED structure. The LED structure 200a is applicable to a wire bonding packaging structure or a flip chip packaging structure.

As shown in FIG. 2A and FIG. 2B, the LED structure 200a includes a substrate 202, a light-emitting structure 214, at least one SP structure 220a, a first electrode 232, and a second electrode 228. The light-emitting structure 214 is capable of growing on the substrate 202. In certain embodiments, the material of the substrate 202 includes, for example, sapphire, silicon carbide (SiC), gallium nitride (GaN) or silicon (Si). A surface of the substrate 202 selectively includes a regular-shape structure or an irregular-shape structure to facilitate light scattering, thereby enhancing the light extraction efficiency.

As shown in FIG. 2B, in the LED structure 200a, the light-emitting structure 214 is stacked by an epitaxial structure and a conductive layer 212. In the embodiment shown in FIG. 2B, the epitaxial structure includes an undoped semiconductor layer 204, a first electrical type semiconductor layer 206, an active layer 208, and a second electrical type semiconductor layer 210 sequentially stacked on the substrate 202. In other embodiments, the epitaxial structure may not include the undoped semiconductor layer 204. In addition, the epitaxial structure also, for example, selectively includes a heavily-doped second electrical type semiconductor layer (not shown) disposed between the second electrical type semiconductor layer 210 and the conductive layer 212, so as to enhance the ohmic contact effect with the conductive layer 212. The conductive layer 212 is stacked on the second electrical type semiconductor layer 210 of the epitaxial structure.

In certain embodiments of the present invention, the first electrical type and the second electrical type are different electrical type. For example, one of the first electrical type and the second electrical type is n-type, and the other is p-type. In this exemplary embodiment, the first electrical type is n-type, and the second electrical type is p-type. In some examples, the material of the epitaxial structure includes, for example, gallium nitride (GaN) series materials, such as gallium nitride, aluminum gallium nitride (AlGaN), indium gallium nitride (InGaN) and indium aluminum gallium nitride (InAlGaN). The active layer 208 includes, for example, a multiple quantum well (MQW) structure.

In certain embodiments, when the LED structure 200a is applied to a wire bonding packaging structure, the conductive layer 212 can be, for example, a transparent conductive layer. At this time, the material of the transparent conductive layer 212 is, for example, indium tin oxide (ITO), zinc oxide (ZnO), gallium zinc oxide (GZO), aluminum zinc oxide (AZO) or indium oxide (In₂O₃). Alternatively, when the LED structure 200a is applied to a flip chip packaging structure, the conductive layer 212 can be, for example, an ohmic reflection layer. At this time, the material of the conductive layer 212 is, for example, silver (Ag), or silver/nickel/titanium/platinum (Ag/Ni/Ti/Pt).

In the LED structure 200a, the light-emitting structure 214 includes a mesa structure 256. As shown in FIG. 2B, the mesa structure 256 is formed of the conductive layer 212, the second electrical type semiconductor layer 210, the active layer 208, and a part of the first electrical type semiconductor layer 206. That is, in the light-emitting structure 214, the active layer 208 is located on a portion 258 of the first electrical type semiconductor layer 206 and is exposed from another portion 260 of the first electrical type semiconductor layer 206. Therefore, the mesa structure 256 is located on the portion 258 of the first electrical type semiconductor layer 206.

As shown in FIG. 2B, to fit the number, shapes and locations of the SP structures 220a, one or more grooves 218a having the corresponding shape may be provided at preset locations of the light-emitting structure 214. The groove 218a is disposed in the conductive layer 212 and the second electrical type semiconductor layer 210 of the light-emitting structure 214. The SP structure 220a is correspondingly filled in the groove 218a, that is, the SP structure 220a is concavely disposed in the conductive layer 212 and the second electrical type semiconductor layer 210 of the light-emitting structure 214. FIG. 2C is an enlarged schematic view of a portion 234 in FIG. 2B. As shown in FIG. 2C, in certain embodiments, a side surface 242 of the groove 218a is, for example, an inclined surface that inclines relative to a bottom surface 244 of the groove 218a, so that the SP structure 220a is easily filled in the groove 218a. Alternatively, in some other embodiments, the side surface 242 of the groove 218a is perpendicular to the bottom surface 244. In an embodiment, a distance 248 between the bottom surface 244 of the groove 218a and the active layer 208 is, for example, from 50 Å to 1000 Å. In an exemplary embodiment, the distance 248 between the bottom surface 244 of the groove 218a and the active layer 208 is from 50 Å to 200 Å.

Referring to FIG. 2C again, in an embodiment, the SP structure 220a mainly includes a resonant metal layer 238. The resonant metal layer 238 covers the bottom surface 244 and the side surface 242 of the groove 218a. The material of the resonant metal layer 238 includes, for example, silver, gold, aluminum, titanium or a random combination of the metals. In certain embodiments, when the material of the resonant metal layer 238 is silver, the resonant metal layer 238 is capable of resonating with blue light near the wavelength 430 nm. Alternatively, when the material of the resonant metal layer 238 is gold, the resonant metal layer 238 is capable of resonating with green light. Further, when the material of the resonant metal layer 238 is aluminum, the resonant metal layer 238 is capable of resonating with ultraviolet light. In an embodiment, the thickness of the resonant metal layer 238 is, for example, from 5 Å to 500 Å.

In another embodiment, the SP structure 220a further selectively includes an insulating layer 236. The insulating layer 236 first covers the bottom surface 244 and the side surface 242 of the groove 218a, the resonant metal layer 238 then covers the insulating layer 236, and the material of the insulating layer 236 is, for example, titanium dioxide, aluminum oxide, silicon dioxide or silicon nitride. Further, the thickness of the insulating layer 236 is for example, from 20 Å to 200 Å. In this embodiment, because of the deposition of the insulating layer 236, the SP structure 220a might be excited by photons more easily to generate an electromagnetic field, which subsequently affecting the active layer 208 to generate more photons. Additionally, the insulating layer 236 may prevent that the depth of the groove 218a exceeds the active layer 208, and therefore avoid short circuits.

In yet another embodiment, the SP structure 220a also selectively includes an insulating layer 240. The insulating layer 240 covers the resonant metal layer 238 and can fill the groove 218a. The material of the insulating layer 240 is, for example, titanium dioxide, aluminum oxide, silicon dioxide or silicon nitride. In an embodiment, the refractive index of the material of the insulating layer 236 is greater than the refractive index of the material of the insulating layer 240, so as to prevent total internal reflection of light emitted from the active layer 208 inside the light-emitting structure 214. The insulating layer 240 is disposed to effectively reduce the aspect ratio (depth to width ratio) of the groove 218a or even to achieve a planar effect for the surface of the light-emitting structure 214. Therefore, the problem of undesirable coverage caused by an excessively large aspect ratio of the groove 218a does not occur in the subsequent deposition of the conductive layer 216. In certain embodiments, the insulating layer 240 can completely fill or partly fill the groove 218a. Even if the insulating layer 240 does not completely fill the groove 218a, the effect of reducing the aspect ratio of the groove 218a can still be achieved.

Therefore, in this embodiment, the SP structure 220a can include only the resonant metal layer 238, or include the resonant metal layer 238 and the insulating layer 236 thereunder, or include the resonant metal layer 238 and the insulating layer 240 thereon, or includes the resonant metal layer 238, the insulating layer 236 thereunder, and the insulating layer 240 thereon at the same time.

Further, a width 246 of the bottom surface of the SP structure 220a is, for example, from 10 nm to 5 μm, so as to prevent the SP structure 220a from affecting the even distribution of current in the second electrical type semiconductor layer 210. By designing the range of the width 246 of the bottom surface of the SP structure 220a, the lateral current in the second electrical type semiconductor layer 210 is evenly distributed into the entire second electrical type semiconductor layer 210, so as to prevent uneven current distribution. In a preferred embodiment, the width 246 of the bottom surface of the SP structure 220a is, for example, 0.5 μm to 2 μm.

By the design of the groove 218a, the distance between the resonant metal layer 238 of the SP structure 220a and the active layer 208 is effectively reduced. Therefore, after the metal resonate structure layer 238 acquires the energy transferred by photons emitted by the active layer 208, the generated local electromagnetic field can further effectively excite the active layer 208, making the active layer 208 emit more light. Accordingly, the coupling effect between the resonant metal layer 238 and the active layer 208 can be significantly enhanced, thereby further enhancing the light emitting efficiency of the LED structure 200a.

In an embodiment, as shown in FIG. 2B, the LED structure 200a further selectively includes another conductive layer 216. The conductive layer 216 covers the conductive layer 212 and the SP structure 220a filled in the groove 218a, so as to enhance the evenness of current distribution.

Similarly, when the LED structure 200a is applied to a wire bonding packaging structure, the conductive layer 216 is a transparent conductive layer. At this time, the material of the transparent conductive layer 216 is, for example, indium tin oxide, zinc oxide, gallium zinc oxide, aluminum zinc oxide or indium oxide. Also, the same material or different materials can be selected for the conductive layers 212 and 216. In a preferred embodiment, the refractive indexes of the insulating layers 236 and 240 of the SP structure 220a are greater than the refractive index of the conductive layer 216, so as to prevent total internal reflection of the light emitted from the active layer 208 inside the LED structure 200a.

In another aspect, when the LED structure 200a is applied to a flip chip packaging structure, the conductive layer 216 and the conductive layer 212 are both ohmic reflection layers. At this time, the material of the conductive layer 212 is, for example, silver (Ag), or silver/nickel/titanium/platinum (Ag/Ni/Ti/Pt). When the conductive layer 216 is also an ohmic reflection layer, a barrier layer covers the conductive layer 212 and the conductive layer 216. Preferably, the barrier layer completely covers the conductive layer 212 and conductive layer 216 serving as ohmic reflection layers, so as to prevent the oxidation of the conductive layer 212 and the conductive layer 216. In another embodiment, the conductive layer 216 is a barrier layer. At this time, the material of the conductive layer 216 is, for example, gold/tungsten (Au/W), nickel/platinum/gold/platinum/gold (Ni/Pt/Au/Pt/Au) or titanium tungsten alloy/platinum/titanium tungsten alloy/platinum (TiW/Pt/TiW/Pt). Also, the conductive layer 216 serving as the barrier layer preferably completely covers the conductive layer 212 serving as the ohmic reflection layer, so as to prevent the oxidation of the conductive layer 212.

Referring to FIG. 2A and FIG. 2B again, the first electrode 232 is disposed on the surface of the exposed portion 260 of the first electrical type semiconductor layer 206. The second electrode 228 is disposed on the conductive layer 216 above the conductive layer 212. As shown in FIG. 2A, the first electrode 232 includes an electrode pad 222 and one or more finger-shaped electrodes 230. The finger-shaped electrode 230 is connected to the electrode pad 222. The second electrode 228 includes an electrode pad 224 and one or more finger-shaped electrodes 226. The finger-shaped electrode 226 is connected to the electrode pad 224. In an embodiment, the finger-shaped electrode 230 of the first electrode 232 and the finger-shaped electrode 226 of the second electrode 228 of the LED structure 200a are located at two opposite sides of the light-emitting structure 214, respectively, and are parallel to each other, as shown in FIG. 2A.

In this embodiment, as shown in FIG. 2A, the SP structure 220a of the LED structure 200a can be a plurality of SP bars. These SP bars are substantially parallel to each other. Further, these SP bar are substantially evenly arranged between the finger-shaped electrode 230 of the first electrode 232 and the finger-shaped electrode 226 of the second electrode 228. In an embodiment, as shown in FIG. 2A, these SP bars are substantially perpendicular to the finger-shaped electrode 230 of the first electrode 232, and the finger-shaped electrode 226 of the second electrode 228. Alternatively, these SP bars are substantially parallel to the finger-shaped electrode 230 of the first electrode 232, and the finger-shaped electrode 226 of the second electrode 228.

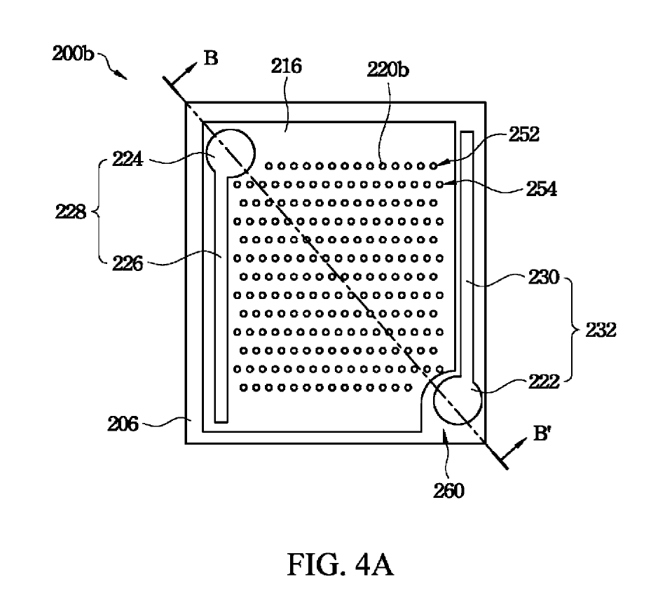

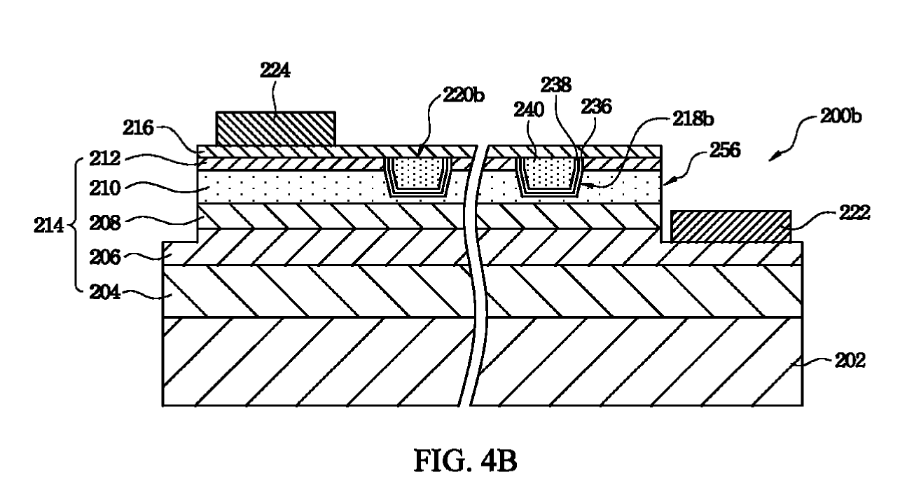

In certain embodiments, the SP structure can also be a structure having other shapes, for example, a dot-shaped structure. FIG. 4A is a top view of an LED structure according to another embodiment of the present invention, and FIG. 4B is a sectional view of the LED structure obtained along the sectional line BB′ in FIG. 4A. The architecture of the LED structure 200b in this embodiment is approximately the same as the architecture of the LED 200a in the above embodiment, and the difference lies in that the at least one SP structure 220b of the LED structure 200b includes a plurality of SP dots, as shown in FIG. 4A.

As shown in FIG. 4B, in the LED structure 200b, to fit the dot structure of the SP structure 220b, the groove 218b of the light-emitting structure 214 is a dot groove. In the LED structure 200b, these SP structures 220b are arranged into several rows 252 and 254. The rows 252 and 254 are substantially parallel to each other. In an embodiment, the SP structures 220b in two adjacent rows 252 and 254 are arranged staggered to each other, as shown in FIG. 4A. Through such a staggered arrangement, the LED structure 200b acquires even light distribution, and the resonant effect between the SP structure 220b and the active layer 208 is taken account of.

Referring to FIG. 4A again, in the LED structure 200b, the top-view shape of the SP structure 220b is circular. Alternatively, in other embodiments, the top-view shape of the SP structure 220b can be a polygonal shape, for example, a hexagonal or square shape. Further, the LED structure 200b is also applicable to a wire bonding packaging structure or a flip chip packaging structure.

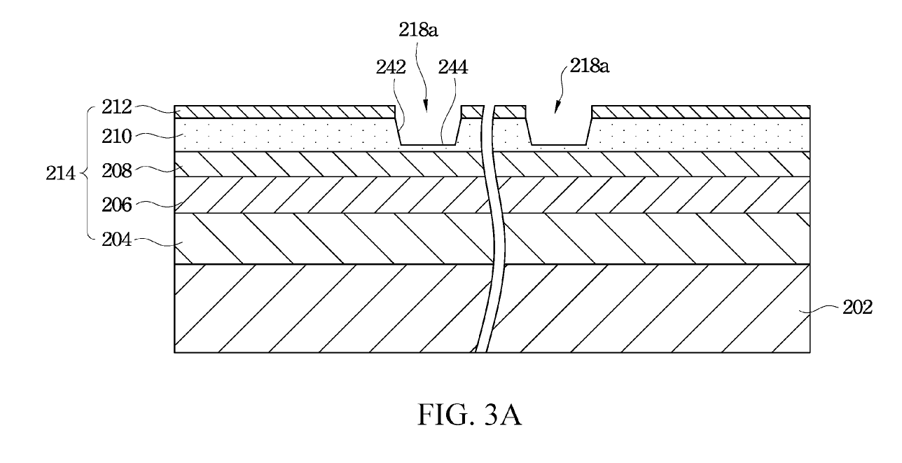

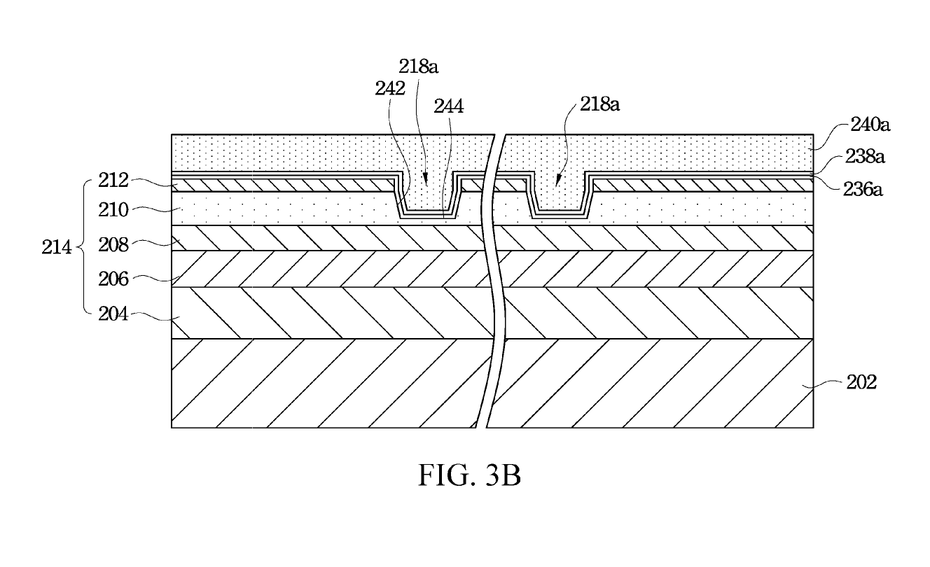

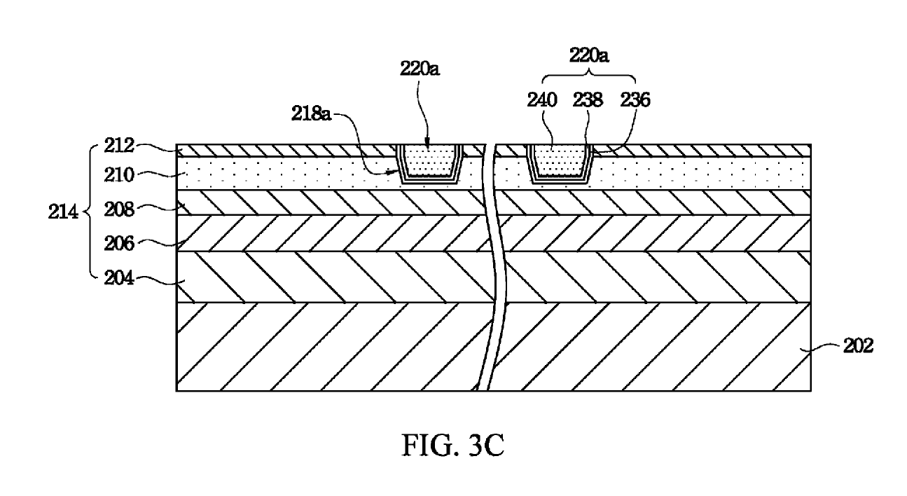

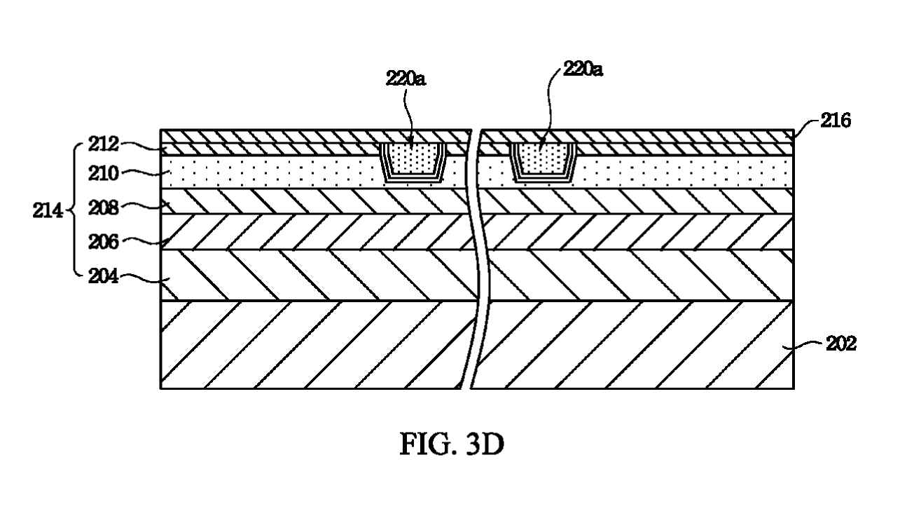

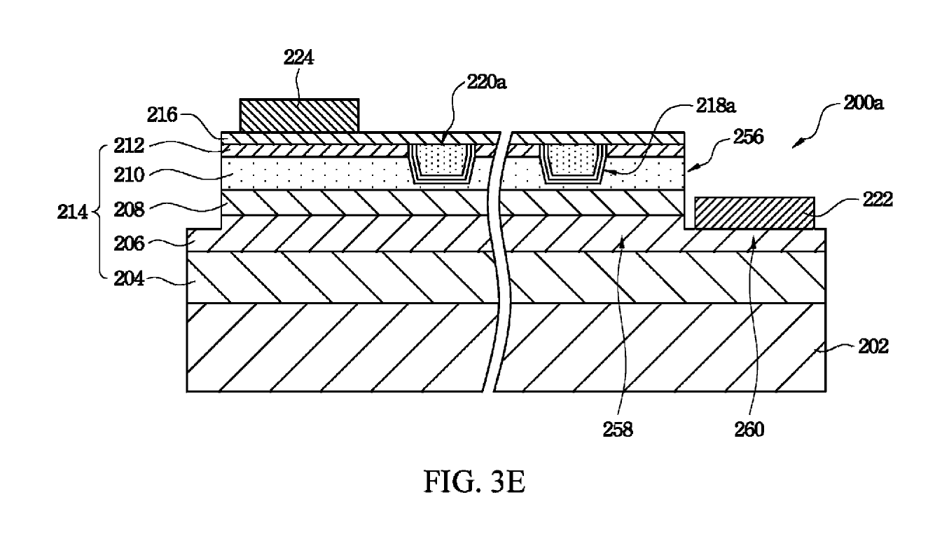

The LED structure 200a shown in FIGS. 2A-2C is taken as an example to illustrate the manufacturing of an LED structure of the present invention. FIG. 3A to FIG. 3E are sectional views of a manufacturing process of an LED structure according to one embodiment of the present invention. To manufacture an LED structure 200a shown in FIG. 3E, a substrate 202 is provided. Next, an undoped semiconductor layer 204, a first electrical type semiconductor layer 206, an active layer 208, and a second electrical type semiconductor layer 210 epitaxially grow on the substrate 202 sequentially through, for example, metalorganic chemical vapor deposition (MOCVD), so as to form an epitaxial structure of the light-emitting structure 214. In another embodiment, the epitaxial structure further selectively includes a heavily-doped second electrical type semiconductor layer (not shown), so that after a second electrical type semiconductor layer 210 has grown, the epitaxy continues to form a heavily-doped second electrical type semiconductor layer on the second electrical type semiconductor layer 210.

Then, a conductive layer 212 is formed on the second electrical type semiconductor layer 210 of the epitaxial structure through, for example, an evaporation or sputtering technique, so as to complete the manufacturing of all material layers of the light-emitting structure 214. After that, as shown in FIG. 3A, the pattern of the light-emitting structure 214 is defined through, for example, a lithography and etching technique, so as to form one or more grooves 218a in the conductive layer 212 and the second electrical type semiconductor layer 210. In an embodiment, when the groove 218a is defined in the light-emitting structure 214, a part of the conductive layer 212 and a part of the second electrical type semiconductor layer 210 are removed through inductively coupled plasma (ICP) etching.

By controlling the etching process, the depth of the groove 218a in the light-emitting structure 214 is controlled. In one embodiment, as shown in FIG. 2C, the distance 248 between the bottom surface 244 of the groove 218a and the active layer 208 is, for example, from 50 Å to 1000 Å. In an exemplary embodiment, the distance 248 between the bottom surface 244 of the groove 218a and the active layer 208 is, for example, from 50 Å to 200 Å. In an embodiment, when the groove 218a is formed, the side surface 242 of the groove 218a is made inclined relative to the bottom surface 244 of the groove 218a, so that the groove 218a has an inclined side surface 242, which facilitates subsequent deposition of the SP structure 220a. Alternatively, in other embodiments, the side surface 242 of the groove 218a can be perpendicular to the bottom surface 244.

Next, as shown in FIG. 3B, an insulating layer 236a is formed covering the conductive layer 212, and the bottom surface 244 and the side surface 242 of the groove 218a by through, for example, deposition. In an embodiment, the thickness of the insulating layer 236a is, for example, from 20 Å to 200 Å. Next, a resonant metal layer 238a is formed covering the insulating layer 236a through, for example, deposition. In an embodiment, the thickness of the resonant metal layer 238a is, for example, from 5 Å to 500 Å. Next, an insulating layer 240a is formed covering the resonant metal layer 238a through, for example, deposition. In an embodiment, the insulating layer 240a completely fills the groove 218a of the light-emitting structure 214, as shown in FIG. 3B.

The material of the insulating layers 236a and 240a is, for example, titanium dioxide, aluminum oxide, silicon dioxide or silicon nitride. In an embodiment, the refractive index of the insulating layer 236a is greater than the refractive index of the insulating layer 240a, so as to prevent total internal reflection of the light emitted from the active layer 208 inside the light-emitting structure 214. The material of the resonant metal layer 238a includes, for example, silver, gold, aluminum, titanium or a random combination of the metals.

Next, the conductive layer 212 is taken as an etching stop layer or a polishing stop layer. A part of the insulating layers 236a and 240a above the conductive layer 212, as well as a part of the resonant metal layer 238a are removed through, for example, etching or chemical-mechanical polishing (CMP). By keeping the insulating layers 236 and 240, as well as the resonant metal layer 238 inside the groove 218a, an SP structure 220a sequentially stacked by the insulating layer 236, the resonant metal layer 238, and the insulating layer 240 is formed inside the groove 218a in the conductive layer 212 and the second electrical type semiconductor layer 210, as shown in FIG. 3C. In an embodiment, as shown in FIG. 2A, these SP structures 220a are substantially parallel to each other.

The width 246 of the bottom surface 244 of the SP structure 220a is, for example, from 10 nm to 5 μm, so as to prevent the SP structure 220a from affecting the even distribution of current in the second electrical type semiconductor layer 210. By designing the range of the width 246 of the bottom surface 244 of the SP structure 220a, the lateral current in the second electrical type semiconductor layer 210 is evenly distributed into the entire second electrical type semiconductor layer 210, so as to prevent uneven current distribution. In a preferred embodiment, the width 246 of the bottom surface 244 of the SP structure 220a is, for example, 0.5 μm to 2 μm.

Next, selectively, another conductive layer 216 is formed covering the conductive layer 212 and the SP structure 220a through, for example, an evaporation or sputtering technique, so as to enhance the evenness of current distribution. When the LED structure 200a is applied to a wire bonding packaging structure, the conductive layers 212 and 216 can be transparent conductive layers. At this time, the material of the conductive layers 212 and 216 is, for example, indium tin oxide, zinc oxide, gallium zinc oxide, aluminum zinc oxide or indium oxide. Further, the same material or different materials can be selected for the conductive layers 212 and 216. In a preferred embodiment, the refractive indexes of the insulating layers 236 and 240 of the SP structure 220a are greater than the refractive index of the conductive layer 216, so as to prevent total internal reflection of the light emitted from the active layer 208 inside the LED structure 200a.

Alternatively, when the LED structure 200a is applied to a flip chip packaging structure, the conductive layer 212 is an ohmic reflection layer, while the conductive layer 216 is a barrier layer. At this time, the material of the conductive layer 212 is silver, or silver/nickel/titanium/platinum; and the material of the conductive layer 216 is gold/tungsten, nickel/platinum/gold/platinum/gold or titanium tungsten alloy/platinum/titanium tungsten alloy/platinum. The conductive layer 216 preferably completely covers the conductive layer 212, so as to prevent the oxidation of the conductive layer 212. In another embodiment, both the conductive layer 212 and the conductive layer 216 are ohmic reflection layers, and then another barrier layer (not shown) completely covers the conductive layer 212 and the conductive layer 216, so as to prevent the oxidation of the conductive layer 212 and the conductive layer 216.

Next, the mesa structure 256 of the LED structure 200a is defined through, for example, a lithography and etching technique. When the mesa structure 256 is defined, a part of the conductive layer 216 and a part of the light-emitting structure 214 are removed till the surface of a portion 260 of the first electrical type semiconductor layer 206 below is exposed, so as to form the mesa structure 256, as shown in FIG. 3E. Therefore, the light-emitting structure 214 formed of a part of the first electrical type semiconductor layer 206, a part of the active layer 208, a part of the second electrical type semiconductor layer 210, and a part of the conductive layer 212, and the conductive layer 216 located on the light-emitting structure 214, are both located on the portion 258 of the first electrical type semiconductor layer 206. In an embodiment, an ICP etching technique is adopted to remove a part of the conductive layer 216 and a part of the light-emitting structure 214.

Subsequently, referring to FIG. 2A and FIG. 3E together, through, for example, an evaporation and lift-off technique, a first electrode 232 is formed on the surface of the exposed portion 260 of the first electrical type semiconductor layer 206, and a second electrode 228 is formed on the conductive layer 216, so as to complete the manufacturing of the LED structure 200a. In an embodiment, the first electrode 232 and the second electrode 228 can include chrome/platinum/gold (Cr/Pt/Au) structures sequentially stacked on the surface of the exposed portion 260 of the first electrical type semiconductor layer 206 and the conductive layer 216. In certain embodiments, the materials of the first electrode 232 and the second electrode 228 are selectively thermally processed according to the device requirements, so that the material layers of the first electrode 232 and the second electrode 228 are annealed, so as to reduce the contact resistance between the second electrode 228 and the conductive layer 216.

As shown in FIG. 2A, the first electrode 232 includes the electrode pad 222 and the one or more finger-shaped electrodes 230, in which the finger-shaped electrode 230 is connected to the electrode pad 222. The second electrode 228 also includes the electrode pad 224 and one or more finger-shaped electrodes 226, and the finger-shaped electrode 226 is connected to the electrode pad 224. In an embodiment, the finger-shaped electrode 230 of the first electrode 232 and the finger-shaped electrode 226 of the second electrode 228 of the LED structure 200a are located on two opposite sides of the light-emitting structure 214, respectively, and are parallel to each other.

In certain embodiments, when the LED structure 200a is applied to a wire bonding packaging structure, the electrode pads 222 and 224 are, for example, electrically connected to two electrodes of an external power supply directly through leads (not shown), respectively. Alternatively, when the LED structure 200a is applied to a flip chip packaging structure, the completed LED structure 200a can be inverted, and the inverted LED structure 200a is connected to another packaging substrate or a circuit substrate (not shown) through, for example, bonding pads.

In the LED structure 200a, the SP structures 220a are substantially evenly arranged between the finger-shaped electrode 230 of the first electrode 232 and the finger-shaped electrode 226 of the second electrode 228. As shown in FIG. 2A, these SP structures 220a are substantially perpendicular to the finger-shaped electrode 230 of the first electrode 232, and the finger-shaped electrode 226 of the second electrode 228. In other embodiments, these SP structures 220a are substantially parallel to the finger-shaped electrode 230 of the first electrode 232, and the finger-shaped electrode 226 of the second electrode 228.

As can be seen through the embodiments, one advantage of the present invention, among other things, is that an SP structure is concavely disposed in a light-emitting structure, the distance between a resonant metal layer of the SP structure and an active layer can be effectively reduced, and the coupling efficiency of the resonant metal layer and the active layer is enhanced, so that the internal quantum efficiency of the LED structure is enhanced.

As can be seen through the embodiments, another advantage of the present invention, among other things, is that total internal reflection inside the LED structure is reduced by adjusting the selection of the insulating material in the SP structure, so that the external quantum efficiency of the LED structure is enhanced.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light-emitting diode (LED) structure, comprising:
a substrate;
a light-emitting structure, disposed on the substrate, and having a first electrical type semiconductor layer, an active layer, a second electrical type semiconductor layer, and a first conductive layer sequentially stacked on the substrate, wherein the active layer is located at a first portion of the first electrical type semiconductor layer and is exposed from a second portion of the first electrical type semiconductor layer, and the first electrical type semiconductor layer and the second electrical type semiconductor layer have different electrical types;
at least one surface plasmon (SP) structure, concavely disposed in the first conductive layer and the second electrical type semiconductor layer; and
a first electrode and a second electrode, disposed on the second portion of the first electrical type semiconductor layer and the first conductive layer, respectively.

2. The LED structure according to claim 1, wherein the SP structure comprises a plurality of SP bars or a plurality of SP dots.

3. The LED structure according to claim 1, wherein the light-emitting structure further comprises at least one groove disposed in the first conductive layer and the second electrical type semiconductor layer, the SP structure is located in the groove, the SP structure comprises a first insulating layer, a resonant metal layer, and a second insulating layer stacked sequentially.

4. The LED structure according to claim 3, wherein the distance between the bottom surface of the at least one groove and the active layer is from 50 Å to 1000 Å.

5. The LED structure according to claim 3, wherein the width of the bottom surface of the at least one SP structure is from 10 nm to 5 μm.

6. The LED structure according to claim 3, wherein the thickness of the resonant metal layer is from 5 Å to 500 Å.

7. The LED structure according to claim 3, wherein the material of the first insulating layer and the second insulating layer comprises titanium dioxide, aluminum oxide, silicon dioxide or silicon nitride.

8. The LED structure according to claim 3, wherein the refractive index of the first insulating layer is greater than the refractive index of the second insulating layer.

9. The LED structure according to claim 3, further comprising a second conductive layer covering the first conductive layer and the SP structure.

10. The LED structure according to claim 9, wherein each of the first conductive layer and the second conductive layer is a transparent conductive layer.

11. The LED structure according to claim 9, wherein the first conductive layer is an ohmic reflection layer, and the second conductive layer is a barrier layer.

12. The LED structure according to claim 1, wherein the SP structure comprises a resonant metal layer.

13. The LED structure according to claim 1, wherein the SP structure comprises an insulating layer and a resonant metal layer covering the insulating layer.

14. A method for manufacturing a light-emitting diode (LED) structure, comprising:
forming a light-emitting structure on a substrate, wherein the light-emitting structure comprises a first electrical type semiconductor layer, an active layer, a second electrical type semiconductor layer, and a first conductive layer sequentially stacked on the substrate, the active layer is located on a first portion of the first electrical type semiconductor layer and is exposed from a second portion of the first electrical type semiconductor layer, and the first electrical type semiconductor layer and the second electrical type semiconductor layer have different electrical types;
forming at least one groove in the first conductive layer and the second electrical type semiconductor layer;
forming at least one surface plasmon (SP) structure in the at least one groove; and
forming a first electrode and a second electrode on the second portion of the first electrical type semiconductor layer and the first conductive layer, respectively.

15. The method for manufacturing an LED structure according to claim 14, wherein the step of forming the SP structure comprises sequentially forming a first insulating layer, a resonant metal layer, and a second insulating layer to be filled in the groove.

16. The method for manufacturing an LED structure according to claim 15, between the step of forming the SP structure and the step of forming the first electrode and the second electrode, further comprising forming a second conductive layer covering the first conductive layer and the SP structure.

17. The method for manufacturing an LED structure according to claim 16, wherein each of the first conductive layer and the second conductive layer is a transparent conductive layer.

18. The method for manufacturing an LED structure according to claim 16, wherein the first conductive layer is an ohmic reflection layer, and the second conductive layer is a barrier layer.

19. The method for manufacturing an LED structure according to claim 14, wherein the step of forming the SP structure comprises forming a resonant metal layer covering the at least one groove.

20. The method for manufacturing an LED structure according to claim 14, wherein the step of forming the SP structure comprises:
forming an insulating layer covering the groove; and
forming a resonant metal layer covering the insulating layer.
